(19) United States
(12) Patent Application Publication
(10) Pub. No.: US 2026/0144014 A1
(43) Pub. Date: May 21, 2026

(54) SEMICONDUCTOR DEVICE WITH DEGRADATION DETECTION CAPABILITY

(71) Applicant: Infineon Technologies AG, Neubiberg (DE)

(72) Inventor: Cristian Mihai BOIANCEANU, Bucharest (RO)

(21) Appl. No.: 19/365,580

(22) Filed: Oct. 22, 2025

(30) Foreign Application Priority Data
Nov. 15, 2024 (DE) 102024133568.8

(51) Int. Cl. H01L 23/00; H01L 21/66

(52) U.S. Cl. CPC H10P 74/27; H10W 72/5363; H10W 90/755

(57) ABSTRACT

A semiconductor device with a power transistor is described herein. The power transistor is composed of a plurality of transistor cells arranged in a cell array, wherein the plurality of transistor cells comprise first transistor cells arranged in a first part of the cell array and second transistor cells arranged in a second part of the cell array. The semiconductor device further includes a metallization layer that forms the source electrode of the power transistor, first bond wires with end pieces that are bonded to a first part of the metallization layer that covers the first part of the cell array, and second bond wires with end pieces that are bonded to a second part of the metallization layer that covers the second part of the cell array. The end pieces of the second bond wires have a higher volume than the end pieces of the first bond wires.

### TECHNICAL FIELD

This description relates to a semiconductor device with a power transistor and degradation detection capability.

### BACKGROUND

One concept for current measurement that is often used in association with power transistors consists in the use of a so-called sense transistor. A power transistor (for example a DMOS transistor) usually consists of a multiplicity of transistor cells connected in parallel (transistor cell array). However, some transistor cells of the cell array form a separate transistor (the sense transistor). The sense transistor can be operated approximately at the same operating point as the power transistor, but has a significantly smaller active area than the power transistor. The currents flowing through power transistor and sense transistor are thus approximately proportional in such an arrangement, wherein the proportionality factor K corresponding (at least theoretically) to the ratio of the active areas of the two transistors. That is, the active area of the sense transistor is smaller than the active area of the power transistor by the factor K.

During operation, the semiconductor chip, which includes the power transistor, may be exposed to a varying thermal load, which can lead—over time—to the degradation of the semiconductor chip and ultimately to the failure of the semiconductor chip. There are concepts for semiconductor chips which can carry out a so-called “health check” using integrated circuitry. However, these concepts are generally restricted to specific applications or they do not identify a problem until it is too late to ensure reliable continuation of operation (fail operational).

### SUMMARY

A semiconductor device with a power transistor is described herein. In one embodiment. the power transistor is composed of a plurality of transistor cells arranged in a cell array, wherein the plurality of transistor cells comprise first transistor cells arranged in a first part of the cell array and second transistor cells arranged in a second part of the cell array. The semiconductor device further includes a metallization layer that forms the source electrode of the power transistor, first bond wires with end pieces that are bonded to a first part of the metallization layer that covers the first part of the cell array, and second bond wires with end pieces that are bonded to a second part of the metallization layer that covers the second part of the cell array. The end pieces of the second bond wires have a higher volume than the end pieces of the first bond wires.

Furthermore a method for operating the wireless device is described herein. In one embodiment, the method includes, detecting whether a resistance formed by a part of the metallization layer and being arranged in series to a load current path of the power transistor has changed by a specific amount, and deactivating the at least a portion of the second transistor cells upon detection that the resistance has changed by a specific amount.

### BRIEF DESCRIPTION OF THE DRAWINGS

Exemplary embodiments are explained in greater detail below with reference to drawings. The illustrations are not necessarily true to scale and the exemplary embodiments are not restricted to only the illustrated aspects. Rather, importance is attached to illustrating the principles underlying the exemplary embodiments. With regard to the drawings:

FIG. 1 illustrates one example of a current measuring circuit which uses a sense transistor for current measurement;

FIG. 2 illustrates the example from FIG. 1 with additional illustration of the resistance of the chip metallization;

FIG. 3 is an image, recorded by means of a microscope, of the surface of a semiconductor chip into which the circuit from FIG. 2 is integrated;

FIG. 4 is a schematic cross-sectional illustration through a semiconductor chip;

FIG. 5 illustrates a circuit in accordance with a first exemplary embodiment, wherein different bond wires are used at to contact different positions of the chip metallization layer.

FIG. 6 illustrates one example of a wire bond interconnect wherein the bond wire has an end piece with an enlarged volume and thus an enlarged heat capacitance to enable a better cooling of the adjoining part of the metallization layer.

FIG. 7 illustrates an alternative bond wire design with a similar effect as the bond wire design of FIG. 6.

FIG. 8 illustrates a conventional wire bond interconnect formed, e.g. by a wedge bonding process.

FIG. 9 illustrates the circuit of FIG. 2 with an additional detection circuit which is configured to detect a degradation of the chip metallization layer by detecting an increased voltage across a specific portion of the chip metallization layer.

FIG. 10 illustrates a circuit, included in the semiconductor device, for deactivating some transistor cells of the cell array forming the power transistor.

FIG. 11 illustrates one example of a system including a microcontroller and a semiconductor device according to one of the embodiments described herein.

FIG. 12 illustrates a flow chart illustrates an embodiment of a method for operating the semiconductor device.

### DETAILED DESCRIPTION

FIG. 1 shows one exemplary implementation of a current measuring circuit comprising a sense transistor. In the depicted example, an electrical load R_{LOAD} is switched by means of a power transistor T_{L}. The current flowing through the power transistor T_{L} and hence also through the load R_{LOAD} is designated by i_{LOAD}. The power transistor T_{L} may be a high-side switch as shown in FIG. 1. That is, the main current path of the power transistor T_{L} (drain-source current path in the case of a MOS transistor) is connected between a supply terminal VS and an output (output pin OUT), to which the load R_{LOAD} can be connected. It is understood that the present disclosure is not limited to high-side transistors. The concepts described herein may readily be applied to circuits with low-side switches.

A current sense circuit, which includes a sense transistor T_{S}, is coupled to the power transistor T_{L}. The current sense circuit is configured to provide a measurement current i₀ that represents the load current i_{LOAD} passing through the power transistor T_{L}. As mentioned in the introduction, the sense current i₀ is approximately proportional to the load current i_{LOAD}, i.e. i₀=i_{LOAD}/K (proportionality factor K). For a current measurement, the transistors T_{S} and T_{L} must have the same (or at least similar) characteristics and be operated (approximately) at the same operating point. Therefore, the gate electrodes of the two transistors T_{L} and T_{S} are connected to one another. Likewise the drain electrodes. Further, in a high-side arrangement, the drain electrodes of the transistors T_{L} and T_{S} are connected to the supply terminal VS, at which a supply voltage V_{S} is present during operation.

In order that both transistors T_{L} and T_{S} are operated at the same operating point, the drain-source voltages at both transistors T_{L} and T_{S} should be identical. In the depicted embodiment, this is achieved with the aid of the operational amplifier OA and the further transistor T₀ which together ensure that the source voltage at the sense transistor T_{S} is regulated to the same value as the source voltage at the power transistor T_{L}. It is noted that the operational amplifier is not necessary. Other concepts exist for ensuring the (approximate) proportionality between measurement current i₀ and load current i_{LOAD}. The specific implementation will depend on the requirements of the application.

In the example of FIG. 1, the sense transistor T_{S} and the further transistor T₀ (i.e. their main current paths) are connected in series, so that the same measurement current i₀ flows through both transistors, T_{S} and T₀. In the depicted example, the transistor T₀ is a p-channel MOS transistor, whereas the transistors T_{S} and T_{L} are n-channel MOS transistors. The gate of the transistor T₀ is driven by the output signal of the operational amplifier OA, wherein the inputs of the operational amplifier OA are coupled to the source electrodes of the transistors T_{S} and T_{L}. It is understood that a similar circuit can also be constructed with a p-channel transistor as power transistor (and sense transistor).

The operational amplifier OA and the transistor T₀ together implement a feedback loop. The inverting input of the operational amplifier OA is connected to the source electrode of the sense transistor T_{S}, and the noninverting input of the operational amplifier OA is connected to the source electrode of the power transistor T_{L}. If the source voltage at the sense transistor T_{S} is less than the source voltage at the power transistor T_{L}, then the voltage at the output of the operational amplifier O_{A} rises. As a result, the gate-source voltage at the transistor T₀ becomes smaller, which has the effect that the on-resistance of the transistor T₀ rises, which has the effect that the source voltage at the sense transistor T_{S} increases. Accordingly, feedback loop of the operational amplifier OA is stable and, consequently, the operational amplifier OA drives the transistor T₀ such that the voltages at the source electrodes of the transistors T_{L} and T_{S} are substantially equal, i.e. differences in the drain-source voltages of power transistor and sense transistor are compensated for. As a result, sense transistor and power transistor operate substantially at the same operating point.

In the example of FIG. 1, the sense current i₀ is output at a sense pin IS, and the output current at pin IS is denoted i_{S} (i_{S}=i₀ in the present example). A sense resistor R_{S} may be connected to the sense pin IS. The sense resistor R_{S} is usually connected between the sense pin IS and a reference voltage (e.g. ground potential, 0 V). The resulting voltage V_{IS} at the sense pin IS is then equal to the product of the current i_{S} and the resistance R_{S} (V_{IS}=R_{S}·i_{S}=i_{LOAD}·R_{S}/K).

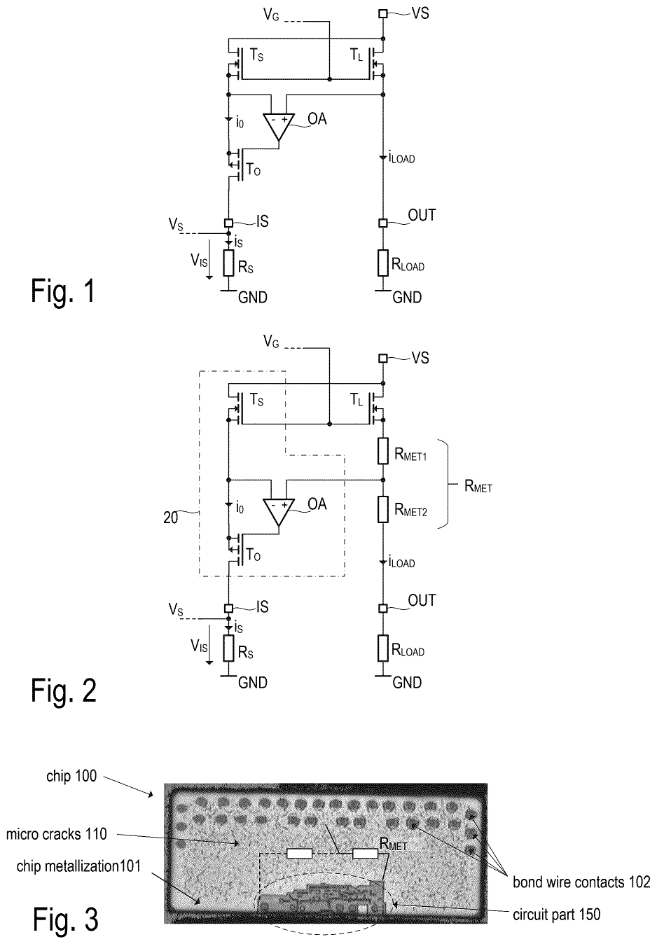

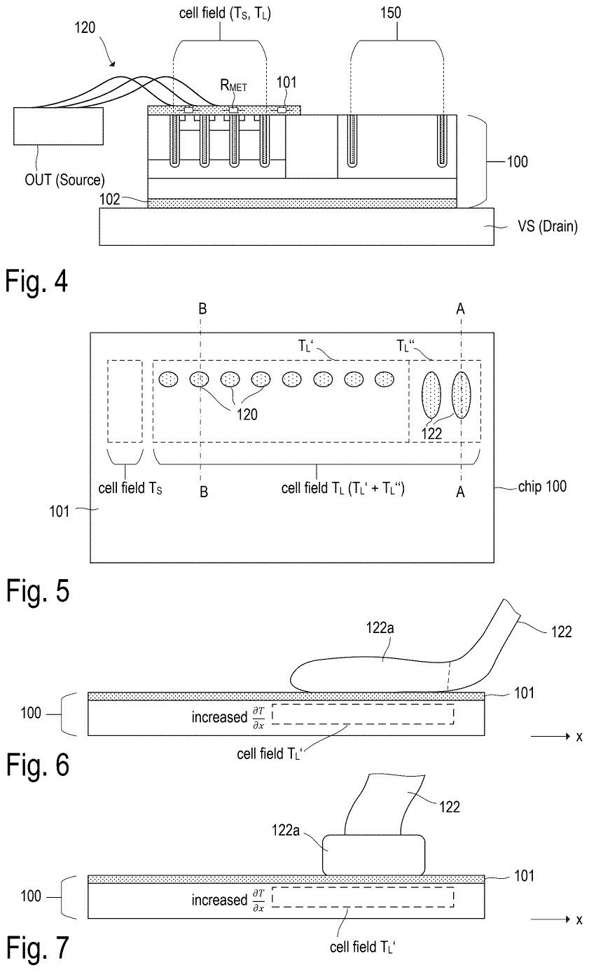

FIG. 2 illustrates the same circuit as from FIG. 1 with the sole difference that a resistance R_{MET} is arranged between the source electrode of the power transistor TL and the output pin OUT. The resistances R_{MET} is formed (inter alia) by the chip metallization and may thus be regarded as parasitic resistance. In fact, the resistance R_{MET} may be decomposed into two resistances, R_{MET1} and R_{MET2}, that form a voltage divider, wherein the non-inverting input of the operational amplifier OA is connected to the middle tap of the voltage divider. The resistances of interconnects (e.g. vias or plated-through holes connecting different metallization layers) also contribute to these resistances R_{MET1} and/or R_{MET2}. The resistance R_{MET} is a lateral resistances, i.e. the current through these resistances passes substantially in a lateral direction (i.e. substantially parallel to the chip surface), whereas the transistors T_{L} and T_{S} may be vertical transistors (see also FIG. 4), in which the current flows substantially “from top to bottom” through the transistor cell array in a direction that is substantially perpendicular to the chip surface,.

FIG. 3 shows an enlarged image (photograph), taken by means of a microscope, of the semiconductor chip 100 which includes the circuit from FIG. 2. The image of the semiconductor chip 100 shows the chip metallization 101 which covers most of the chip surface. Furthermore, FIG. 3 illustrates contact locations 102 for bond wires connecting the chip metallization 101 to the output pin OUT of the chip 100. The output pin OUT itself cannot be seen in FIG. 3 because it is usually arranged on a leadframe on which the chip 100 is mounted.

Furthermore, FIG. 3 illustrates a circuit part 150 including the majority of the circuits required for driving and for operating the power transistor T_{L} as well as for the current measurement by means of the sense transistor. As mentioned, the power and sense transistors can be embodied as vertical transistors and be formed by a multiplicity of transistor cells of a cell array. In the case of vertical transistors, the drain-source current path runs from the top side of the semiconductor chip (visible in FIG. 3), through the chip to the bottom side of the chip. In the depicted example of FIG. 3, the chip metallization forming the drain electrode of the transistors T_{S} and T_{L} is situated on the bottom side of the chip, whereas the chip metallization 101 of the source electrode is arranged on the top side.

A schematic illustration of the resistance R_{MET} is superimposed on the image of the semiconductor chip 100. At this point it is important to understand that the resistance R_{MET} is not a specific circuit component embodied (locally) at a specific location. Rather, the resistance runs in a lateral direction and is distributed over the entire chip metallization 101 (depending on what current density field forms in the metallization during operation).

The chip metallization 101 can be contacted (tapped) at a plurality of locations (e.g. at the node between R_{MET1} and R_{MET2}, see FIG. 2). In the example illustrated in FIG. 3, one contact of the resistance R_{MET} is situated in direct proximity to one of the chip contact locations 102 and a further contact is situated in the vicinity of the circuit part 150, in which for example the operational amplifier OA is also arranged. It is understood that the voltage divider R_{MET1}, R_{MET2} is a simplified model of the reality. The layer thickness of the chip metallization may be in the range of approximately 2-50 μm.

The chip contact locations 102 are for example those locations at which bond wires are connected to the chip metallization (e.g. by means of a wire bonding process). In other exemplary embodiments, clips, ribbons (ribbon bonding) or the like can also be used instead of bond wires. The geometry of the chip contact locations 102 can be different depending on the connection technique used.

The chip metallization 101 may be contacted at a plurality of locations. In the example illustrated in FIG. 3, a further contact is illustrated (on the left) in the vicinity of the circuit part 150. The resistance RMET can then be regarded (in terms of modeling) as an electrical parallel connection of two resistances. The resistance value RMET then represents an average value of different local current paths through the chip metallization 101.

As already mentioned, the semiconductor chip—and also the chip metallization 101—experiences a multiplicity of temperature cycles during operation of the integrated circuit. The temperatures may fluctuate more or less regularly, between room temperature and, e.g. 300° Celsius or more. Cyclic temperature fluctuations of more than 200° Celsius are not unusual. These fluctuations may gradually result in microcracks 110 in the chip metallization 101, and the resistance value R_{MET} gradually increases due to the increasing number of microcracks. Investigations (by monitoring of the resistance value R_{MET}) have shown that for a specific change in the resistance value R_{MET} (e.g. a rise by 200%), a failure of the semiconductor chip became increasingly likely. Monitoring the resistance value R_{MET} therefore allows a prediction that the semiconductor chip is approaching its end of life before the chip actually fails. In the case of safety-critical applications such as e.g. in the case of certain components of autonomously driving vehicles, such a prediction may be a crucial advantage for avoiding greater damage.

Further investigations have shown that the mentioned prediction (based on a monitoring of R_{MET}) may be feasible for power transistors with a very low-ohmic on-resistance. However, for power transistors with a medium or relatively high on-resistance this concept is not feasible due to the comparably small relative changes of resistance R_{MET} (and thus the small relative changes of the respective voltages).

Finally, it is noted that a change of the resistance R_{MET} also affects the proportionality factor K between sense current i₀ and load current i_{LOAD}. This is clear from FIG. 2. If the resistance R_{MET} changes due to defects such as micro cracks, delamination or the like, the voltage at the non-inverting input of the operational amplifier OA will also change. As a result, the operational amplifier OA cannot ensure equal source voltages at the transistors T_{S} and T_{L}.

FIG. 4 is a schematic cross-sectional view of the semiconductor chip of FIG. 3. It is understood that FIG. 4 is not true to scale and includes only the aspects necessary for understanding the exemplary embodiments discussed below. The structure of such a semiconductor chip is as such known to a person skilled in the art.

A transistor cell array integrated in the semiconductor chip 100 is illustrated schematically on the left-hand side of FIG. 4. The depicted example includes vertical DMOS transistors T_{S} and T_{L}. The drain electrode is formed by the metallization 102 at the bottom side of the chip. The source electrode is formed by the metallization 101 at the top side of the chip 100. The bottom-side metallization is mounted on a leadframe, e.g. by means of a die bonding process. The top-side metallization 101 is connected to the chip pin OUT of the leadframe, e.g. by means of a wire bonding process (bond wires 120). The resistance of the metallization 101 is symbolized by the resistance R_{MET} (cf. also FIG. 3). The circuit part 150 containing most of the other circuit components is situated on the right-hand side of FIG. 4. The resistance R_{MET} formed by the chip metallization 101 is formed in particular by that part of the metallization which is exposed to thermal loading during operation of the power transistor T_{L} and degrades due to this (cyclic) thermal loading.

The embodiments described herein, are designed such that the metallization layer 101 has a kind of a target breaking point. This allows, when an actual defect is detected, to deactivate the affected portion of the cell array. Defects usually occurs close to the locations, at which the bond wires connect the metallization layer, wherein the thermal load causes (thermo-) mechanical stress and strain which again may lead to the mentioned defects such as cracks, delamination, etc. At this point, it is important to understand, that it is the temperature gradient (i.e. a temperature difference between two close points) which causes the mechanical stress and not the temperature as such.

According to the embodiments discussed herein, the mentioned target breaking point (which is more an area than a point) is achieved by designing some specific bond contacts such that the temperature gradient close to these bond contacts is higher than at the other bond contacts. If defects occur during operation of the semiconductor chip, they will occur first at (or close to) these specific bond contacts. Such a defect may be detected (e.g. by detecting a sudden change in the proportionality factor K=i_{LOAD}/i₀), the affected part of the load transistor (i.e. the affected transistor cells) may be deactivated, and an error may be signaled while the power transistor as such remains functional.

FIG. 5 illustrates an embodiment of a semiconductor device. The device includes a semiconductor chip 100, in which a power transistor T_{L} is integrated. The power transistor may be composed of a plurality of transistor cells arranged in a cell array. According to the depicted example, the plurality of transistor cells can be subdivided into first transistor cells (denoted T_{L}′) arranged in a first part of the cell array and second transistor cells (denoted as T_{L}″) arranged in a second part of the cell array. A metallization layer 101 forms the source electrode of the power transistor, which is composed of the first and second transistor cells.

A plurality of bond wires are bonded to the metallization layer 101. More specifically, bond wires 120 with end pieces 120a are bonded to a first part of the metallization layer 101 that covers the first part of the cell array and bond wires 122 with end pieces 122a are bonded to a second part of the metallization layer 101 that covers the second part of the cell array. The second part of the cell array may be only a small portion of the total cell array.

The end pieces 122a of the second bond wires 122 have a higher volume than the end pieces 120a of the first bond wires 120. That is, two different types of bond wires are used, wherein the two types of bond wires differ essentially in the shape (the geometry) of their end pieces. The higher volume of the end pieces 122a of the bond wires 122 (as compared to the end pieces of bond wires 120) usually comes with a higher contact area. The contact areas of the bond wires are illustrated by gray-shaded ellipses in FIG. 5. As can be seen from the drawing, the contact areas between the bond wires 122 and the metallization layer 101 are significantly larger than the contact areas between the bond wires 12 and the metallization layer 101.

Due to the higher volume of their end pieces, the end pieces 122a of the bond wires 122 have a higher heat capacitance than the end pieces 120a of the first bond wires 120 (for a given material, which may be, for example, copper or aluminum). The higher heat capacitance of the end pieces 122a and/or the higher contact area results in a better local cooling of the metallization layer 101 in the immediate vicinity of the respective bond wires 122, whereas the cooling is less effective in the vicinity of the bond wires of the other type (bond wires 120). A better local cooling results in a higher temperature gradient ∂T/∂x which leads to a higher thermomechanical stress, and the defects in the metallization layer 101 discussed above will occur first in the vicinity of the bond wires 122.

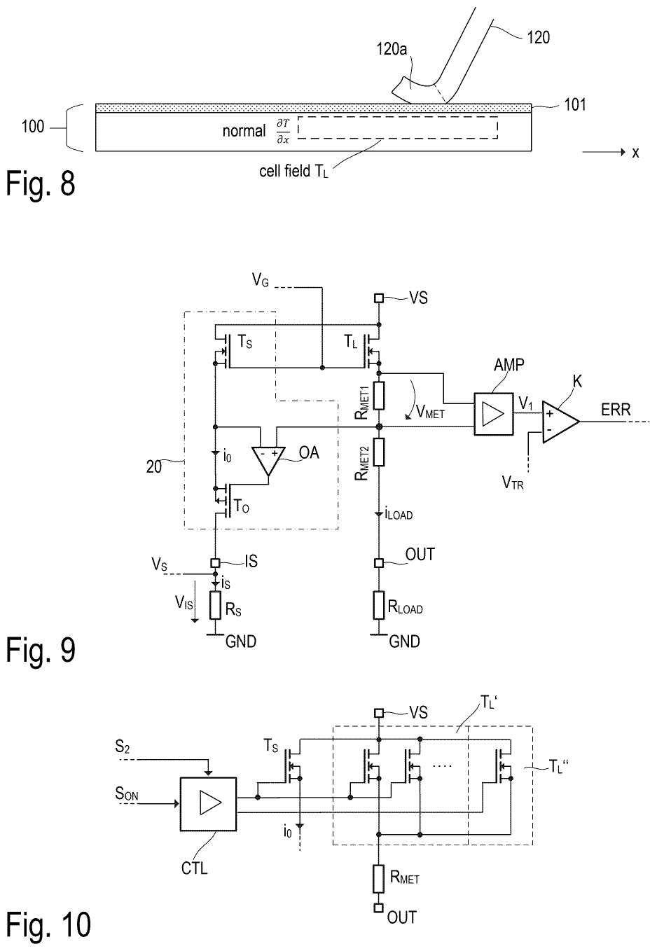

FIG. 6 is a sectional view (sectional plane A, see FIG. 5) of the semiconductor die 100. The section runs through the second part T_{L}′ of the cell array. According to FIG. 6, the end piece 122a of the bond wire touches the metallization layer 101 along a relatively long length, so that the contact area in which the end piece 122a of the bond wire 122 physically touches the metallization layer 101 is comparably large (e.g. larger than for conventional wedge-bonded interconnects, see FIG. 8). FIG. 7 illustrates an alternative embodiment. In this example, the end piece 122a of the bond wire 122 is significantly thicker than the rest of the bond wire which also leads to an enlarged contact area between the end piece 122a and the metallization layer 101.

FIG. 8 is a sectional view (sectional plane B, see FIG. 5) of the semiconductor die 100, wherein, in this example, a conventional wire bond is shown (bond wire 120 with small end piece 120a). When comparing FIG. 8 to FIG. 6 or 7, one can see that, in FIG. 8, the contact area, in which the end piece 120a physically touches the metallization layer 101 is much smaller than in the examples of FIGS. 6 and 7. As a consequence, the volume of end pieces 120a is smaller than the volume of end pieces 122a. Further, the thermal resistance between bond wires 120 (FIG. 8) and the metallization layer 101 is higher than the thermal resistance between bond wires 122 (FIGS. 6 and 7) and the metallization layer 101. As a consequence, the cooling of the semiconductor chip 100 via the bond wires 122 is better than via the bond wires 120 and, as a further consequence, higher temperature gradients ∂T/∂x can occur in the vicinity of the bond wires 122, whereas the temperature gradients ∂T/∂x in the vicinity of the bond wires 120 are lower. Therefore, as mentioned above, during operation of the device (which includes a cyclical thermal load) defects will occur first in the vicinity of the bond wires 122 (FIG. 6 or 7).

The wire bond shown in the example of FIG. 8 may be formed using a wedge bonding process. The wire bond shown in the example of FIG. 7 may be formed using a kind of a ball bonding process. The wire bond shown in the example of FIG. 6 may require a specifically adapted bond tool. Wire bonding is a very well-understood process and the skilled person will be able to modify/optimize bonding tools to achieve the wire bonds with the desired geometry.

Defects like a partial delamination of metallization layer or the degradation of the metallization layer due to an increasing number of cracks can be detected by monitoring the voltage drop that occurs across a part of the metallization layer. This voltage drop may be compared with a specific (preset) threshold value, and a defect may be indicated when the voltage drop exceeds the specific threshold. As the part of the metallization layer in the vicinity of the bond wires 122 are designed as a kind of target breaking point, it is known where the defect occurred, and the affected part of the transistor cell array can be deactivated.

The circuit of FIG. 9 illustrates one example of how a defect/a degradation may be detected. The circuit of FIG. 9 is the same as in FIG. 2 with an additional amplifier AMP and a comparator K. The amplifier AMP and the comparator K form a detection circuit that is configured to detect a voltage drop V_{MET} occurring across a part of the metallization layer (represented by resistance R_{MET1} in the present example) and to indicate that the voltage drop V_{MET} exceeds a specific threshold. In the present example, the amplifier outputs the amplified voltage V₁ (V₁=g·V_{MET} with gain g) and comparator K indicates whether the condition V₁>V_{TR} is fulfilled. Accordingly, the output of the comparator K signals (output signal ERR) whether the voltage drop V_{MET} exceeds the threshold V_{TR}/g. The comparator output signal ERR may be logic signal which has either a Low level or a High level. For example, a High level of the signal ERR may indicate the detection of a defect of the metallization layer 101.

The circuit of FIG. 10 illustrates one example of a control circuit CTL that is configured to switch the power transistor on and off in accordance with a switching command. The switching command may be a rising/falling edge of a logic signal SON received by the control circuit CTL. The control circuit CTL may further be configured to cause deactivation of at least a portion of the second transistor cells (labelled T_{L}'′ in FIG. 10, see also FIG. 5) when the detection circuit (amplifier AMP and comparator K, see FIG. 9) indicates that the voltage drop V_{MET} exceeds the specific threshold (e.g. V_{TR}/g). In the depicted embodiment, the control circuit CTL deactivates the transistor cells T_{L}″ based on the logic level of signal S₂. The signal S₂ may correspond to or depend on the comparator output signal ERR.

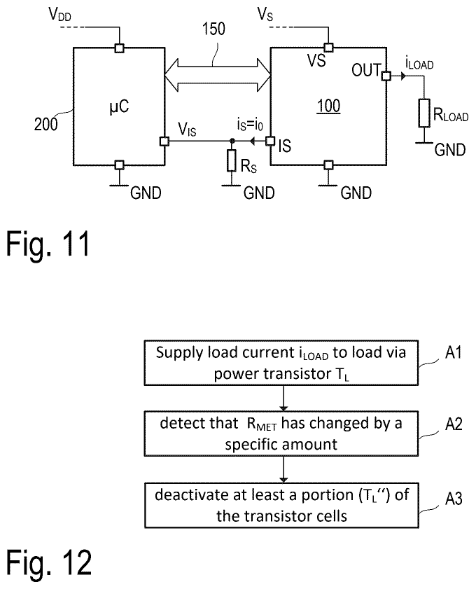

FIG. 11 illustrates a system including the semiconductor device 100 (in a chip package) and a microcontroller 200, which is configured to control the switching operation of the semiconductor device 100. In the present example, the microcontroller 200 is supplied by a supply voltage V_{DD} which may be lower than the supply voltage V_{S} that is applied to the load R_{LOAD}. The microcontroller 200 is configured to receive information concerning the load current i_{LOAD}. In the depicted example, the microcontroller 200 has an analog input which receives the current sense signal V_{IS}=i_{LOAD}·R_{S}/K. The factor R_{S}/K is a known system parameter, wherein K is the proportionality factor discussed above with reference to FIG. 1 and R_{S} denotes the resistance of the sense resistor (also labelled R_{S} in FIG. 10). The microcontroller 200 may be configured to digitize the voltage VIS and calculate a load current value based on the respective digital value. It is understood that the current information may also be digitized in the semiconductor device 100 and transmitted to the microcontroller via a digital communication link 150. In the depicted example, the digital communication link 150 may be any digital communication link, such as parallel or a serial bus, or any other digital link. In one example, a Serial Peripheral Interface (SPI) bus may be used.

As discussed above, at least a portion of the second transistor cells T_{L}″ (see FIGS. 5 and 10) may be deactivated upon the detection of a defect in the metallization layer. This will change the proportionality factor K=i_{LOAD}/i₀ which is relevant for the current measurement. More specifically, the proportionality factor K changes because the ratio of the active areas of the power transistor T_{L} and the sense transistor T_{S} changes. When some transistor cells of the power transistor T_{L} are deactivated, the active area of the power transistor decreases while the active area of the sense transistor T_{S} is constant. However, as the transistor cells, which will be deactivated upon the detection of a defect are a-priori known, the microcontroller 200 can consider the change of the proportionality factor K in the calculation of the actual load current.

The change of the proportionality factor K due to the deactivation of some transistor cells also allows the microcontroller 200 to (indirectly) detect a degradation of the metallization layer 101 of the semiconductor 100. If the microcontroller “sees” a sudden change of the level of the (digitized) current sense signal V_{IS}, it can infer, that a portion of the transistor cells have been deactivated in the semiconductor device 100, wherein the deactivation has been caused by the detection of a defect in the metallization layer. For example, during a pulse-width modulation (PWM) of the load current i_{LOAD}, the current sense signal V_{IS} may suddenly change from one PWM cycle to the next one. The microcontroller 200 may then change the factor K used for calculating the actual load current i_{LOAD} and signal an error to, for example, a superordinate controller device (e.g. via a digital communication link).

In one embodiment, the microcontroller 200 may be configured to deactivate the (at least a portion of) the second transistor cells T_{L}″. In this case, the signal level of signal S₂ (see FIG. 10) is determined by the microcontroller, while the comparator output signal ERR (see FIG. 9) is transmitted to the microcontroller 200 (e.g. via the communication link 150 or a dedicated signal line).

The concept described above is now summarized with reference to the flow chart of FIG. 12. FIG. 12 illustrates one example of a method for operating a semiconductor device which comprises a power transistor (see, e.g., FIG. 1-2, 5, and 10, transistor T_{L}) composed of a plurality of transistor cells arranged in a cell array. The plurality of transistor cells include first transistor cells (collectively denoted as T_{L}′ in the examples of FIGS. 5 and 10) arranged in a first part of the cell array and second transistor cells (collectively denoted as T_{L}″ in the examples of FIGS. 5 and 10) arranged in a second part of the cell array. A metallization layer that forms the source electrode of the power transistor, wherein first bond wires (see FIGS. 5 and 8, bond wires 120) are bonded to a first part of the metallization layer that covers the first part of the cell array and second bond wires (see FIGS. 5-7 122) that are bonded to a second part of the metallization layer that covers the second part of the cell array. As discussed in detail above, the end pieces of the second bond wires have a higher volume than the end pieces of the first bond wires. Additionally or alternatively, the thermal resistance between the individual bond wires and the metallization layer is higher for the first bond wires (e.g. due to the smaller contact area, see FIG. 8). According to FIG. 12, the method includes supplying a load current to a load via the power transistor (FIG. 12, box A1), detecting that a resistance (see FIG. 9, R_{MET1}) formed by the metallization layer and being arranged in series to a load current path of the power transistor has changed by a specific amount (FIG. 12, box A2), and deactivating (FIG. 12, box A3) at least a portion of the second transistor cells (see FIGS. 5 and 10, cells T_{L}″) upon the detection that the resistance has changed by the specific amount (which indicates a degradation of the metallization layer).

In one embodiment, the detection whether the resistance of the metallization layer (e.g. R_{MET1}) has changed by a specific amount is accomplished by amplifying the voltage drop across the resistance and comparing the amplified voltage drop with a threshold value (see also FIG. 9).

In one embodiment, the method further includes transmitting an indication that a degradation of the metallization layer has been detected to a superordinate controller device, e.g. the microcontroller 200 (see FIG. 11). In this case, the superordinate controller device may cause the deactivation of the second transistor cells T_{L}″ (see FIG. 10).

In one embodiment, the method includes generating, using a current sense circuit including a sense transistor (see FIGS. 1-2), a current sense signal that represents a sense current passing through the sense transistor (see FIG. 3, sense current i_{S}=i₀, current sense signal V_{IS}). The superordinate controller (e.g. microcontroller 200, see FIG. 11) may receive the current sense signal and calculate the actual load current therefrom. As already explained above, the superordinate controller may consider a change of the proportionality factor K=i_{LOAD}/i₀ for this calculation.

Although the invention has been illustrated and described with respect to one or more implementations, alterations and/or modifications may be made to the illustrated examples without departing from the spirit and scope of the appended claims. In particular regard to the various functions performed by the above described components or structures (units, assemblies, devices, circuits, systems, etc.), the terms (including a reference to a “means”) used to describe such components are intended to correspond—unless otherwise indicated—to any component or structure, which performs the specified function of the described component (e.g., that is functionally equivalent), even though not structurally equivalent to the disclosed structure, which performs the function in the herein illustrated exemplary implementations of the invention.

1. A semiconductor device comprising:
a power transistor (T_{L}) composed of a plurality of transistor cells arranged in a cell array; the plurality of transistor cells comprising first transistor cells arranged in a first part of the cell array and second transistor cells (T_{L}″) arranged in a second part of the cell array;
a metallization layer that forms the source electrode of the power transistor (T_{L});
first bond wires with end pieces that are bonded to a first part of the metallization layer that covers the first part of the cell array; and
second bond wires with end pieces that are bonded to a second part of the metallization layer that covers the second part of the cell array,
wherein the end pieces of the second bond wires have a higher volume than the end pieces of the first bond wires.

2. The semiconductor device of claim 1,
wherein the second end pieces are shaped such that they effect a better cooling of the metallization layer than the first end pieces.

3. The semiconductor device of claim 1,
wherein the end pieces of the second bond wires have a higher heat capacitance than the end pieces of the first bond wires.

4. The semiconductor device of any of claim 1,
wherein the contact area between the end pieces of the second bond wires and the metallization layer is larger than the contact area between the end pieces of the first bond wires and the metallization layer.

5. The semiconductor device of claim 1, further comprising:
a current sense circuit including a sense transistor (T_{S}), the current sense circuit being configured to provide a current sense signal (V_{IS}) representing a sense current (i₀) passing through the sense transistor (T_{S}), the sense current (i₀) being a fraction of a load current (i_{LOAD}) passing through the power transistor (T_{L}).

6. The semiconductor device of claim 1 further comprising:
a detection circuit (AMP, K) that is configured to detect a voltage drop (V_{MET}) occurring across a part of the metallization layer and to indicate that the voltage drop exceeds a specific threshold (V_{TR}/K).

7. The semiconductor device of claim 6,
wherein the detection circuit includes an amplifier (AMP) that is configured to amplify the voltage drop (V_{MET}), and
wherein the detection circuit is configured to detect that the amplified voltage (V₁) drop exceeding a voltage threshold (V_{TR}).

8. The semiconductor device of claim 7, further comprising:
a control circuit configured to cause deactivation of at least a portion of the second transistor cells (T_{L}″) upon detection of a degradation of the metallization layer.

9. The semiconductor device of claim 8,
wherein the degradation of the metallization layer is indicated by the voltage drop exceeding the specific threshold (V_{TR}/K).

10. A system comprising:
a semiconductor device comprising:
a power transistor (T_{L}) composed of a plurality of transistor cells arranged in a cell array; the plurality of transistor cells comprising first transistor cells arranged in a first part of the cell array and second transistor cells (T_{L}″) arranged in a second part of the cell array;
a metallization layer that forms the source electrode of the power transistor (T_{L});
first bond wires with end pieces that are bonded to a first part of the metallization layer that covers the first part of the cell array; and
second bond wires with end pieces that are bonded to a second part of the metallization layer that covers the second part of the cell array,
wherein the end pieces of the second bond wires have a higher volume than the end pieces of the first bond wires;
a microcontroller configured to receive the current sense signal (V_{IS}) from the semiconductor device and further configured to determine a measured value of the load current (i_{LOAD}) based on the current sense signal (V_{IS});
a current sense circuit including a sense transistor (T_{S}), the current sense circuit being configured to provide a current sense signal (V_{IS}) representing a sense current (i₀) passing through the sense transistor (T_{S}), the sense current (i₀) being a fraction of a load current (i_{LOAD}) passing through the power transistor (T_{L}); and
wherein microcontroller is further configured to compensate for a sudden change of a proportionality factor (K/R_{S}) between the load current (i_{LOAD}) and the current sense signal (V_{IS}).

11. A method for detecting the degradation of a semiconductor device which comprises
a power transistor (T_{L}) composed of a plurality of transistor cells arranged in a cell array; the plurality of transistor cells comprising first transistor cells arranged in a first part of the cell array and second transistor cells (T_{L}″) arranged in a second part of the cell array;
a metallization layer that forms the source electrode of the power transistor (T_{L});
first bond wires with end pieces that are bonded to a first part of the metallization layer that covers the first part of the cell array; and
second bond wires with end pieces that are bonded to a second part of the metallization layer that covers the second part of the cell array,
wherein the end pieces of the second bond wires have a higher volume than the end pieces of the first bond wires;
wherein the method comprises:
detecting a degradation of the metallization layer by detecting whether a resistance (R_{MET}) formed by a part of the metallization layer and being arranged in series to a load current path of the power transistor (T_{L}) has changed by a specific amount,
deactivating the at least a portion of the second transistor cells (T_{L}″) upon detection that the resistance (R_{MET}) has changed by a specific amount.

12. The method of claim 11 further comprising:
generating, using a current sense circuit including a sense transistor (T_{S}), a current sense signal (V_{IS}) that represents a sense current (i₀) passing through the sense transistor (T_{S}).

13. The method of claim 11,
wherein a detected degradation of the metallization layer is indicated to a superordinate controller device.

14. The method of claim 13,
wherein the deactivation of at least a portion of the second transistor cells (T_{L}″) is caused by the superordinate controller device.
